(19) United States
(12) Patent Application Publication
(10) Pub. No.: US 2024/0266290 A1
(43) Pub. Date: Aug. 8, 2024

(54) INTEGRATED CIRCUIT INCLUDING BACKSIDE WIRING PATTERN

(71) Applicant: Samsung Electronics Co., Ltd., Suwon-si (KR)

(72) Inventor: Byounggon Kang, Suwon-si (KR)

(21) Appl. No.: 18/433,327

(22) Filed: Feb. 5, 2024

(30) Foreign Application Priority Data
Feb. 8, 2023 (KR) 10-2023-0016991
May 22, 2023 (KR) 10-2023-0065880

(51) Int. Cl. H01L 23/528; H01L 27/088; H01L 29/06; H01L 29/417; H01L 29/423; H01L 29/775; H01L 29/786

(52) U.S. Cl. CPC H01L 23/5286; H01L 27/088; H01L 29/0673; H01L 29/4175; H01L 29/42392; H01L 29/775; H01L 29/78696

(57) ABSTRACT

An integrated circuit includes a substrate and a plurality of standard cells on the substrate. A standard cell of the plurality of standard cells includes a backside wiring pattern arranged on a lower portion of the substrate and including at least an internal connection node of the standard cell and a plurality of gate lines arranged on an upper portion of the substrate and extending in a first horizontal direction. At least one of the plurality of gate lines functions as an input pin of the standard cell.

### CROSS-REFERENCE TO RELATED APPLICATION(S)

This application is based on and claims priority under 35 U.S.C. § 119 to Korean Patent Application Nos. 10-2023-0016991, filed on Feb. 8, 2023, and 10-2023-0065880, filed on May 22, 2023, in the Korean Intellectual Property Office, the disclosure of each of which is incorporated by reference herein in its entirety.

### BACKGROUND

The inventive concept relates to an integrated circuit, and more particularly, to an integrated circuit including a backside wiring pattern.

Due to the demand for high degree of integration and the development of a semiconductor process, the width, gap space, and/or height of the wires in the integrated circuit may be reduced, and thus, the influence of a parasitic element of the wiring may be increased. In addition, the voltage of the power supply for the integrated circuit has been reduced for reducing power consumption and increasing operation speed, and thus, the parasitic element of the wiring may have much more influence on the integrated circuit.

In addition, due to the miniaturization of the semiconductor manufacturing process, the pattern size of a standard cell may be reduced, and as a result, the size of the standard cell may also be reduced. As the size of the standard cell is reduced, the density of the cell pattern is increased in the standard cell and the density of the lines for interconnecting semiconductor devices is also increased. Thus, there has been increasingly needed an improved method of efficiently arranging the lines for interconnecting semiconductor devices.

### SUMMARY

The inventive concept provides an integrated circuit in which the degree of freedom in routing is increased.

In addition, the problems to be solved by the inventive concept are not limited to the above-described problems, and some other problems are clearly understood by one of ordinary skill in the art from the following descriptions hereinafter.

According to an aspect of the inventive concept, there is provided an integrated circuit including a substrate and a plurality of standard cells on the substrate. A standard cell of the plurality of standard cells includes a backside wiring pattern arranged on a lower portion of the substrate and including at least an internal connection node of the standard cell, and a plurality of gate lines arranged on an upper portion of the substrate and extending in a first horizontal direction. At least one of the plurality of gate lines functions as an input pin of the standard cell.

According to another aspect of the inventive concept, there is provided an integrated circuit including a substrate and a plurality of standard cells on the substrate. A standard cell of the plurality of standard cells includes a backside wiring pattern arranged on a lower portion of the substrate including at least an internal connection node of the standard cell, a frontside wiring pattern arranged on an upper portion of the substrate including an input pin configured to receive an input signal and an output pin configured to output an output signal, and a backside contact connecting the backside wiring pattern to an active region of the substrate and penetrating the substrate.

According to another aspect of the inventive concept, there is provided an integrated circuit including a substrate and a plurality of standard cells on the substrate. A standard cell of the plurality of standard cells includes a backside wiring pattern arranged on a lower portion of the substrate including at least an internal connection node of the standard cell, a plurality of gate lines arranged on an upper portion of the substrate and extending in a first horizontal direction, a plurality of active regions arranged on the upper portion of the substrate and extending in a second horizontal direction perpendicular to the first horizontal direction, and a plurality of active contacts in contact with the plurality of active regions, respectively. At least one of the plurality of active contacts functions as an output pin of the standard cell.

### BRIEF DESCRIPTION OF THE DRAWINGS

Embodiments will be more clearly understood from the following detailed description taken in conjunction with the accompanying drawings in which:

FIG. 1 is a view for explaining an integrated circuit according to an embodiment;

FIG. 2 is a view illustrating an example of a standard cell in an integrated circuit according to an embodiment, and more particularly, is a layout for explaining an AND-OR-INVERTER circuit;

FIGS. 3A and 3B are cross-sectional views cut along line X1-X2 of FIG. 2, and FIGS. 3C and 3D are cross-sectional views cut along line X3-X4 of FIG. 2, according to example embodiments;

FIGS. 4 to 6, 7A, and 8 are views illustrating other examples of the standard cells in the integrated circuit according to embodiments, and more particularly, are layouts for explaining an AND-OR-INVERTER circuit;

FIG. 7B is a cross-sectional view cut along line X5-X6 of FIG. 7A according to example embodiments;

FIGS. 9A, 10, and 11 are views illustrating other examples of the standard cells in the integrated circuit according to example embodiments, and more particularly, are layouts for explaining a flip-flop circuit;

FIG. 9B is a cross-sectional view cut along line X7-X8 of FIG. 9A according to example embodiments;

FIG. 12 is a flowchart showing a method of manufacturing an integrated circuit, according to an embodiment;

FIG. 13 is a block diagram showing a system-on-chip according to an embodiment; and

FIG. 14 is a block diagram showing a computing system including a memory for storing a program according to an embodiment.

### DETAILED DESCRIPTION OF THE EMBODIMENTS

Hereinafter, embodiments of the inventive concept are described in detail with reference to the accompanying drawings. The same reference numerals denote the same elements in the drawings, and the descriptions on the same elements are omitted.

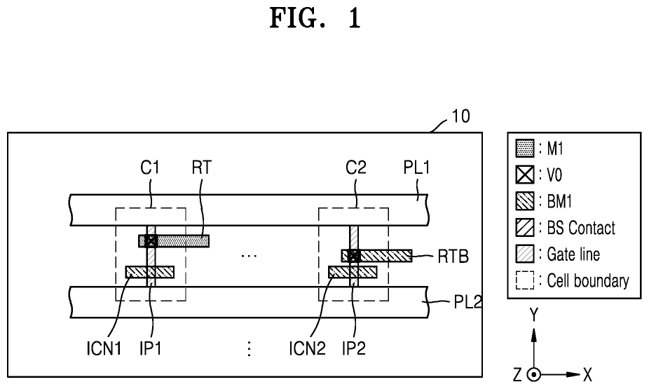

FIG. 1 is a view for explaining an integrated circuit 10 according to an embodiment. FIG. 1 is a plan view illustrating a portion of the integrated circuit 10 including a single chip or a single functional block in a plane defined by an X-axis and a Y-axis. Herein, the X-axis direction and the Y-axis direction may be referred to as a first horizontal direction and a second horizontal direction, respectively, and a Z-axis direction may be referred to as a vertical direction. The plane defined by the X-axis and the Y-axis may be referred to as a horizontal plane, and an element that is positioned in a direction toward the Z-axis, or in a +Z-axis, with respect to another element may be referred to as being on or over the other element, while an element that is positioned in a direction opposite to the Z-axis, or in a −Z-axis, with respect to another element may be referred to as being under or below the other element. The X-axis direction may be perpendicular to the Y-axis direction.

The integrated circuit 10 may include a plurality of standard cells. The standard cell may be a unit of a layout in the integrated circuit 10 and be defined by a cell boundary. The standard cell may be designed to perform a predefined function and may be referred to as a cell. The integrated circuit 10 may include a plurality of various standard cells, and the standard cells may be arranged in a plurality of rows.

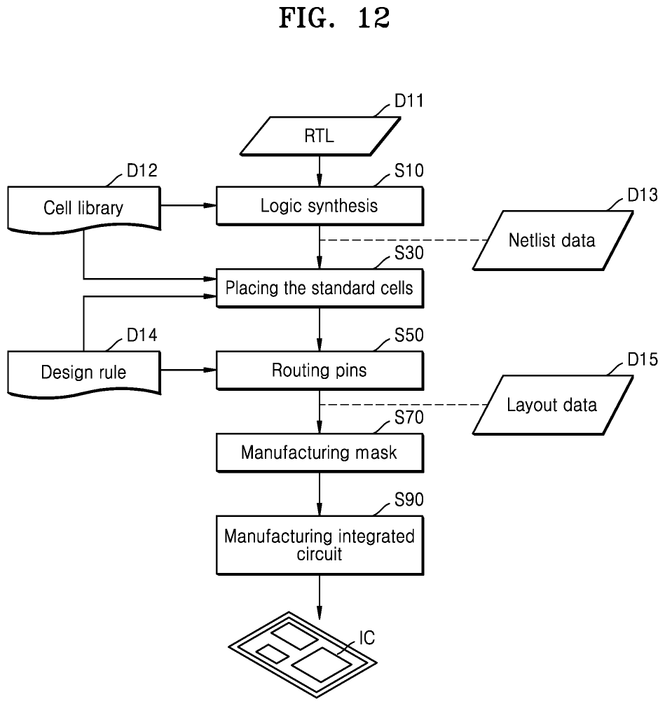

The plurality of standard cells may be repeatedly used in designing the integrated circuit 10. The standard cells may have been pre-designed by the conventional manufacturing technology and be stored in a cell library D12 in FIG. 12, and the integrated circuit 10 may be designed by placing and interconnecting the standard cells in the cell library D12 according to design rules.

A diffusion break may be provided in the cell boundary of the standard cell to electrically separate the standard cell from another standard cell. Due to the diffusion break, neighboring active regions may be separated from each other, and a gate line may not be provided in the diffusion break. The diffusion break may include a double diffusion break or a single diffusion break. The diffusion break may include a silicon-containing insulating layer such as a silicon oxide layer, a silicon nitride layer, a silicon oxynitride layer, a silicon carbide nitride layer, and a combination thereof. For example, the diffusion break may include fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and tonen silazane (TOSZ).

For example, the standard cells may include various basic circuits, such as inverters, AND gates, NAND gates, OR gates, XOR gates, and NOR gates, which are frequently used in digital circuit design for electronic apparatuses, such as a central processing unit (CPU), a graphics processing unit (GPU), and system-on-chip (SoC) designs. In addition, the standard cells may include other circuits that are frequently used for circuit blocks, such as a flip-flop and a latch.

The standard cells may include an active region and a gate line. The active region and the gate line in the standard cell may be formed into a transistor. In an embodiment, the gate line may include a work function metal-containing layer and a gap-fill metal layer. For example, the work function metal-containing layer may include at least one of titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd), and the gap-fill metal layer may include any one of tungsten (W) and aluminum (Al). In an embodiment, the gate line may include a stacked structure of titanium aluminum carbide layer/titanium nitride layer/tungsten layer (TiAlC/TiN/W), a stacked structure of titanium nitride layer/tantalum nitride layer/titanium aluminum carbide layer/titanium nitride layer/tungsten layer (TiN/TaN/TiAlC/TiN/W), and a stacked structure of titanium nitride layer/tantalum nitride layer/titanium nitride/titanium aluminum carbide layer/titanium nitride layer/tungsten layer (TiN/TaN/TiN/TiAlC/TiN/W).

The integrated circuit 10 may include at least a metal layer in which the wirings for interconnecting the standard cells are formed. For example, the integrated circuit 10 may include a frontside metal layer that is stacked on or over an upper surface of a substrate and a backside metal layer that is stacked on or over a lower surface of the substrate.

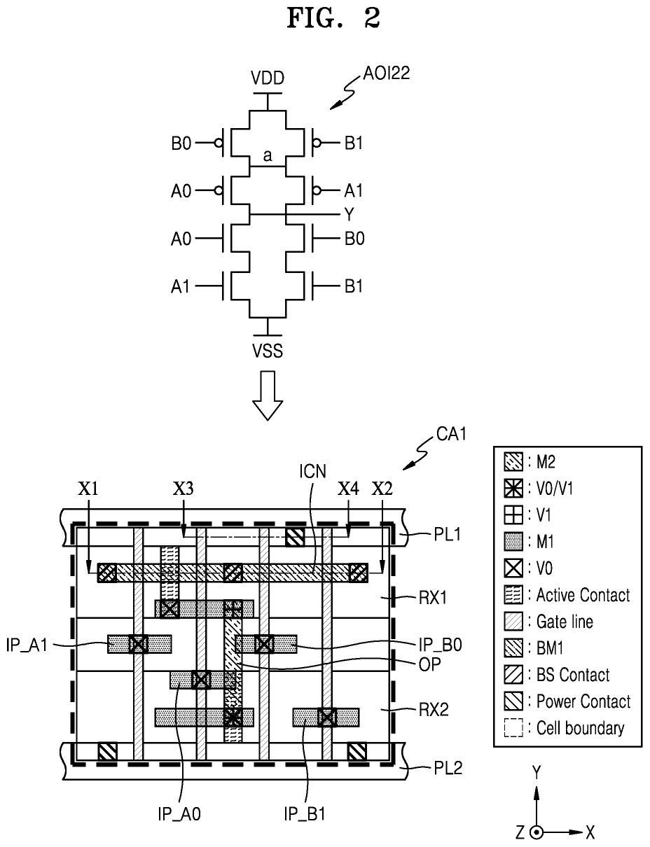

The frontside metal layer may include a first metal layer M1 that is closest to the substrate and a second metal layer M2 in FIG. 2 may be formed on the first metal layer M1. Herein, a pattern in each layer of the frontside metal layer may be referred to as a frontside wiring pattern. In an embodiment, the first metal layer M1 may include a plurality of patterns extending in the X-axis direction, and the second metal layer M2 may include a plurality of patterns extending in the Y-axis direction but is not limited thereto. At least an additional metal layer may be further formed on the second metal layer M2.

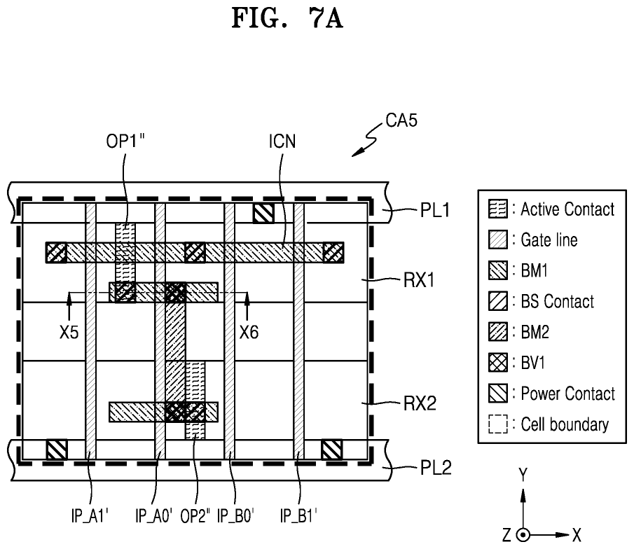

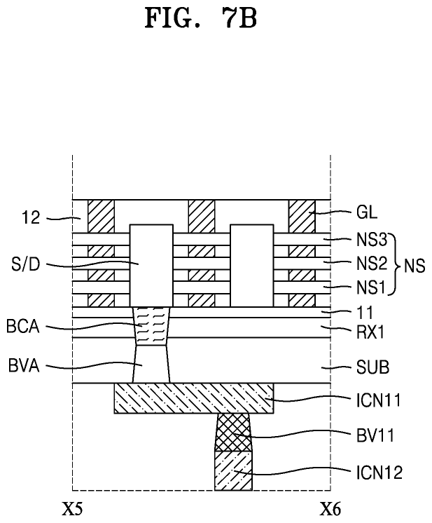

The backside metal layer may include a first backside metal layer BM1 that is closest to the substrate. In addition, the backside metal layer may further include a second backside metal layer BM2 in FIG. 7A on a lower surface of the first backside metal layer BM1. Herein, a pattern in each layer of the backside metal layer may be referred to as a backside wiring pattern. In an embodiment, the first backside metal layer BM1 may include a plurality of patterns extending in the X-axis direction, and the second backside metal layer BM2 may include a plurality of patterns extending in the Y-axis direction but is not limited thereto.

The plurality of patterns in each of the metal layers may include a metal, a conductive metal nitride, a metal silicide, and a combination thereof. In the drawings, only some of the layers may be shown for convenience of illustration, and vias and contacts may also be shown for convenience of illustration for indicating the connection between the pattern of the metal layer and a lower pattern under the metal layer although the vias and the contacts are arranged below the pattern of the metal layer.

A first power line PL1 and a second power line PL2 for supplying voltages to the standard cells may be provided at boundary portions of each of the plurality of rows in which the standard cells are placed. The first power line PL1 may provide a first supply voltage, for example, a power voltage VDD, to each standard cell, and the second power line PL2 may provide a second supply voltage, for example, a ground voltage VSS, to each standard cell. For example, the first power line PL1 and the second power line PL2 may be formed into a conductive pattern extending in the X-axis direction and be alternately arranged in the Y-axis direction.

Referring to FIG. 1, the integrated circuit 10 may include a first standard cell C1 and a second standard cell C2. The first standard cell C1 and the second standard cell C2 may be inner patterns of the cells and may include a backside wiring pattern formed on the backside metal layer, for example, the first backside metal layer BM1. The first standard cell C1 may include a first backside wiring pattern ICN1 functioning as an internal connection node, and the second standard cell C2 may include a second backside wiring pattern ICN2 functioning as an internal connection node. In addition, the first standard cell C1 may further include an additional backside wiring pattern that is connected to an input pin of the first standard cell C1 or an output pin of the first standard cell C1, and the second standard cell C2 may further include an additional backside wiring pattern that is connected to an input pin of the second standard cell C2 or an output pin of the second standard cell C2.

Each of the first standard cell C1 and the second standard cell C2 may include a gate line extending in the Y-axis direction. In an embodiment, the gate line (or a gate contact in contact with the gate line) of the first standard cell C1 may be provided as a first input pin IP1 that receives an input signal from the outside. In an embodiment, the gate line (or a gate contact in contact with the gate line) of the second standard cell C2 may be provided as a second input pin IP2 that receives an input signal from the outside. In another embodiment unlike the configurations shown in FIG. 1, the frontside metal layer, for example, the frontside wiring pattern of the first metal layer M1, may be provided as the first input pin IP1 of the first standard cell C1, and the frontside wiring pattern of the frontside metal layer may be provided as the second input pin IP2 of the second standard cell C2. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The first standard cell C1 may be connected to a first routing wiring RT for interconnection with other standard cells, a gate contact that is a frontside contact between the first routing wiring RT and the first input pin IP1, and/or a via of the first via layer V0. The gate contact may be in contact with the gate line as the first input pin IP1, and for example, the first routing wiring RT may be provided on the first metal layer M1.

Since the first input pin IP1 of the first standard cell C1 functions as the gate line instead of being provided on the metal layer, the first standard cell C1 may receive an input signal through the first routing wiring RT that is electrically connected to the gate line, or the first input pin IP1, the gate contact, and the via of the first via layer V0. The first routing wiring RT, the front gate contact, and the via of the first via layer V0, which are provided as a configuration for transferring the input signal, may be freely arranged at a position overlapping the gate line as the first input pin IP1 in the Z-axis direction.

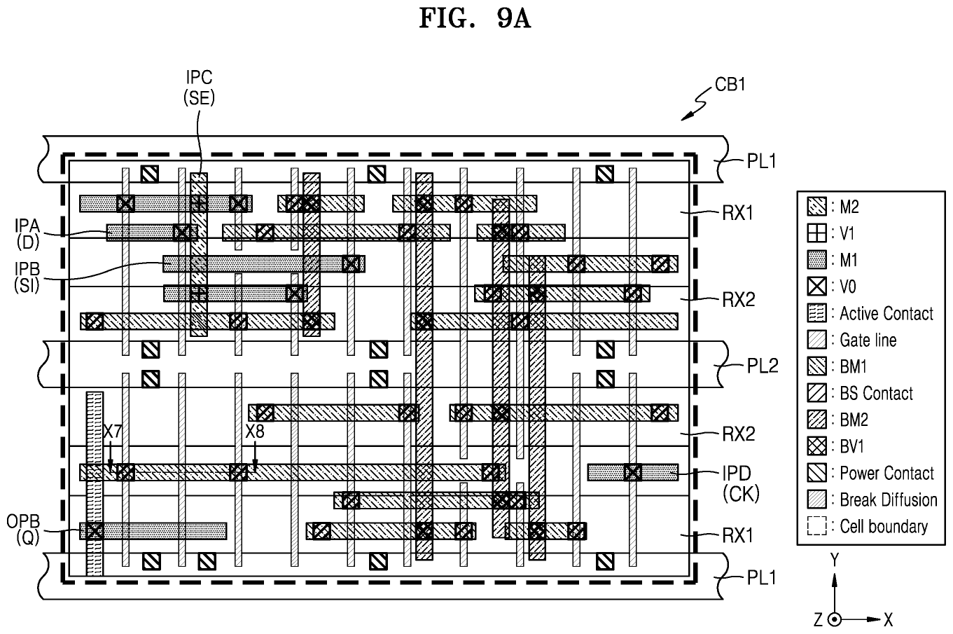

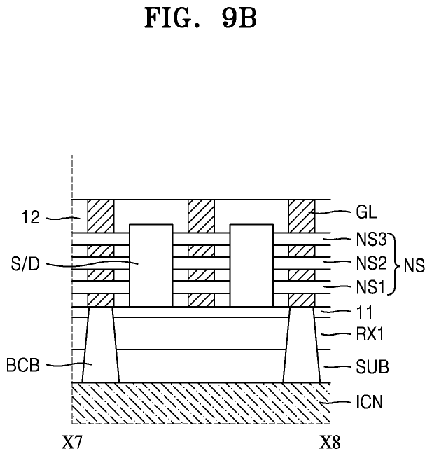

The second standard cell C2 may be connected to a second routing wiring RTB for interconnection with other standard cells and a gate contact BCB in FIG. 9B that is a backside (BS) contact between the second routing wiring RTB and the second input pin IP2. The backside contact may be in contact with the gate line as the second input pin IP2, and for example, the second routing wiring RTB may be provided on the first backside metal layer BM1.

Since the second input pin IP2 of the second standard cell C2 functions as the gate line instead of being provided on the metal layer, the second standard cell C2 may receive an input signal through the second routing wiring RTB that is electrically connected to the gate line, as the second input pin IP2 and the backside contact. The second routing wiring RTB and the backside contact, which are provided as a configuration for transferring the input signal, may be freely arranged at a position overlapping the gate line as the second input pin IP2 in the Z-axis direction.

FIG. 1 shows that the integrated circuit 10 includes the first standard cell C1, the second standard cell C2, the first routing wiring RT connected to the first standard cell C1 and formed on the frontside metal layer, and the second routing wiring RTB connected to the second standard cell C2 and formed on the backside metal layer, but the configuration of the integrated circuit 10 is not limited thereto. All the routing wirings, which are connected to the standard cells of the integrated circuit 10, may be formed only on the frontside metal layer or only on the backside metal layer.

Each of the first standard cell C1 and the second standard cell C2 of the integrated circuit 10 according to an embodiment may include the backside wiring pattern ICN1 or ICN2 that is formed into the internal connection node, to thereby increase the degree of freedom of the routing wirings by which the first standard cell C1 and the second standard cell C2 are individually connected to other standard cells of other integrated circuit. By reducing the complexity of the routing wirings, power loss caused by the RC characteristics of routing wiring may be reduced, to thereby improve the performance and reliability of the designed integrated circuit 10.

In addition, since the first standard cell C1 and the second standard cell C2 includes the first input pin IP1 and the second input pin IP2 that are formed into the gate line, respectively, the arrangement of the first routing wiring RT, the frontside contact, and the via of the first via layer V0 may be properly modified according to another standard cell adjacent to the first standard cell C1 and the arrangement of the second routing wiring RTB and the backside contact may be properly modified according to another standard cell adjacent to the second standard cell C2. Accordingly, the degree of freedom in the arrangement of the routing wirings for transmitting the input signal to each of the first standard cell C1 and the second standard cell C2 may increase.

FIG. 2 is a view illustrating an example of a standard cell CA1 in an integrated circuit 10 according to an embodiment, and more particularly, is a layout for explaining an AND-OR-INVERTER circuit AOI22. An upper part of FIG. 2 shows a circuit diagram of the AND-OR-INVERTER circuit AOI22 and a lower part of FIG. 2 schematically shows the layout of the standard cell CA1 corresponding to the AND-OR-INVERTER circuit AOI22 in a plane defined by the X-axis and Y-axis.

Referring to FIG. 2, first to fourth input signals A0, A1, B0, and B1 may be input to the AND-OR-INVERTER circuit AOI22, and an output signal Y may be output from the AND-OR-INVERTER circuit AOI22. The AND-OR-INVERTER circuit AOI22 may include four N-type transistors and four P-type transistors. Depending on the function of the AND-OR-INVERTER circuit AOI22, when at least one of the first input signal A0 and the second input signal A1 is a low-level logic signal and at least one of the third input signal B0 and the fourth input signal B1 is a low-level logic signal, the AND-OR-INVERTER circuit AOI22 may output a high-level logic signal as the output signal Y.

The standard cell CA1 may include a plurality of gate lines (or gate electrodes) extending in the Y-axis direction and a first active region RX1 and a second active region RX2 extending in the X-axis direction. The first active region RX1 may be referred to as a p-channel field effect transistor (PFET) region, and the second active region RX2 may be referred to as an n-channel field effect transistor (NFET) region.

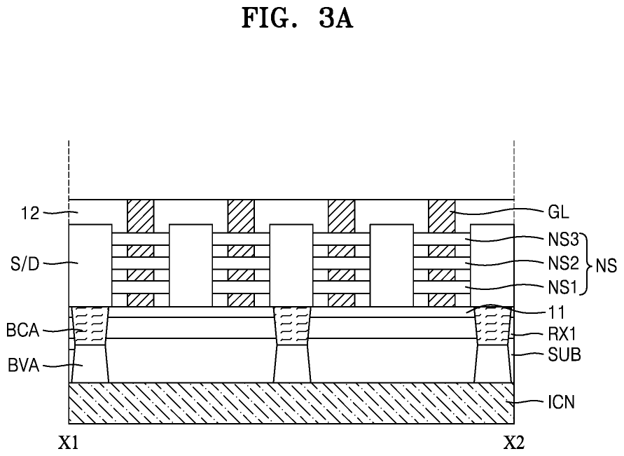

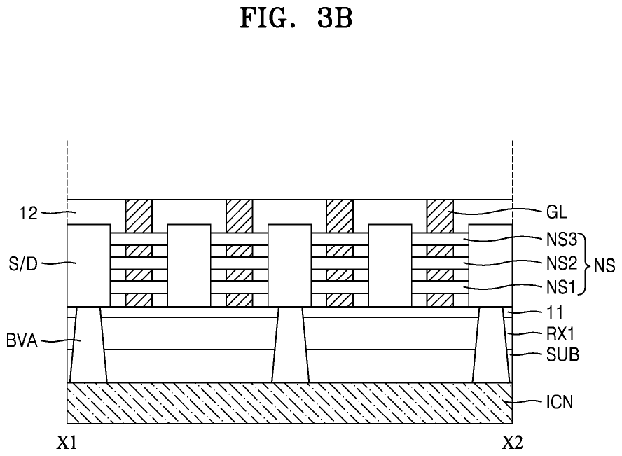

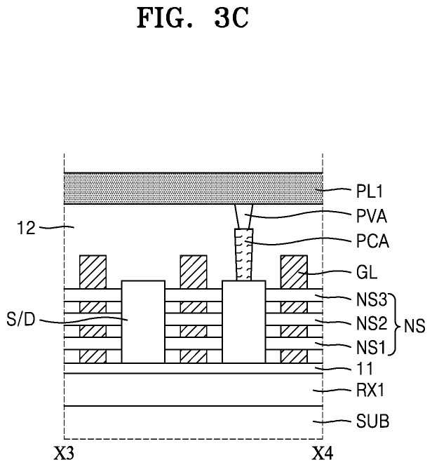

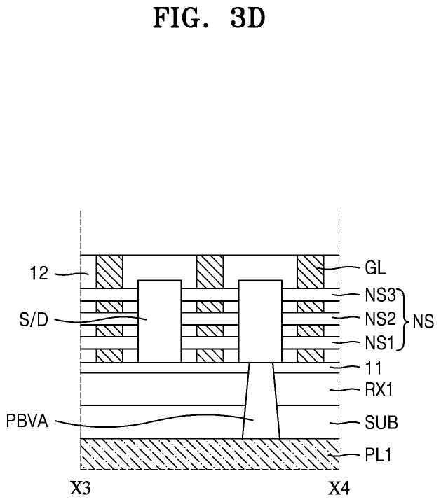

Some portions protruding from each of the first active region RX1 and the second active region RX2 in the Z-axis direction and extending in the X-axis direction may be referred to as active patterns and may form a transistor with the gate lines. A source/drain S/D may be provided on both sides of the gate line, and active contacts, which are the frontside contacts, may be provided on the source/drain S/D, and then, channels may be provided between the source and the drain of the source/drain S/D under the gate line. As an example of the channel, a nanosheet is described below with reference to FIGS. 3A to 3D. The via of the first via layer V0 may be positioned on the frontside contact, and the via of the first via layer V0 may be connected to the frontside contact and the pattern of the first metal layer M1. The via of a second via layer V1 may be electrically connected to the pattern of the first metal layer M1 and the pattern of the second metal layer M2.

The standard cell CA1 may include a first input pin IP_A0 to which a first input signal A0 is input, a second input pin IP_A1 to which a second input signal A1 is input, a third input pin IP_B0 to which a third input signal B0 is input, a fourth input pin IP_B1 to which a fourth input signal B1 is input, and an output pin OP from which the output signal Y is output. In an embodiment, some patterns of the first metal layer M1 may be formed into the first to fourth input pins IP_A0, IP_A1, IP_B0, and IP_B1, and a pattern of the second metal layer M2, which is provided on the first metal layer M1, may be formed into the output pin OP.

The backside wiring pattern ICN may be provided as the internal connection node of the standard cell CA1, for example, the ‘a’ node. Accordingly, a space for forming the routing wiring may increase on the frontside metal layer, to thereby increase the degree of freedom of the routing wiring. The backside wiring pattern ICN may be connected to the source and drain of the first active region RX1 through the backside contact.

According to the standard cell CA1, only the pattern for transmitting the first to fourth input signals A0, A1, B0, and B1, such as the first to fourth input pins IP_A0, IP_A1, IP_B0, and IP_B1 and the pattern for transmitting the output signal Y may be provided on the frontside metal layer M1 or M2, and the backside wiring pattern, which is formed on the first backside metal layer BM1, may be provided as the internal connection node for transmitting the other inner signals of the standard cell CA1.

FIGS. 3A and 3B are cross-sectional views cut along line X1-X2 of FIG. 2, and FIGS. 3C and 3D are cross-sectional views cut along line X3-X4 of FIG. 2, according to example embodiments. Although not shown in FIGS. 3A to 3D, a gate spacer may be formed on a side surface of the gate line GL, and a barrier layer may be formed on the surface of the contact and/or the via.

FIGS. 3A to 3D show various embodiments including a nanosheet on the first active region RX1 and the second active region RX2. Descriptions on the embodiments in FIGS. 3A to 3D are given with reference to FIG. 3A to 3D together with FIG. 2.

For example, a multi bridge channel (MBC) field effect transistor (FET) may be formed in the standard cell CA1 in such a configuration that a plurality of nanosheets are stacked over the first active region RX1 and the second active region RX2 and surrounded by the gate line GL. However, the standard cell in the integrated circuit 10 according to an embodiment is not limited to those illustrated in FIGS. 3A to 3D. For example, a fin FET including a fin and the gate line GL on the active region may be formed in the standard cell CA1, and a gate-all-around (GAA) FET in which a nanowire over the active region is enclosed by the gate line GL may be formed in the standard cell CA1. For example, a plurality of nanowires may be vertically stacked over the active region and each of the nanowires is enclosed by the gate line GL, so that a vertical GAAFET may be formed in the standard cell CA1. In addition, for example, a negative capacity (NC) FET may be formed on the active region. In addition to the aforementioned transistors, various transistors, such as a complementary FET (CFET), a carbon nanotube (CNT) FET, a bipolar junction transistor, and other three-dimensional transistors, may be formed on the gate line GL and the active region.

The substrate SUB may include a semiconductor, such as silicon (Si) and germanium (Ge), and a III-V compound semiconductor, such as gallium arsenide (GaAs), aluminum gallium arsenide (AlGaAs), indium gallium arsenide (InGaAs), indium antimonide (InSb), gallium antimonide (GaSb), indium gallium antimonide (InGaSb), indium phosphide (InP), indium gallium phosphide (InGaP), indium nitride (InN), and indium gallium nitride (InGaN). In an embodiment, the substrate SUB may include a silicon-on-insulator (SOI) substrate and a germanium-on-insulator (GOI) substrate. In an embodiment, the substrate SUB may be doped with p-type impurities.

The first active region RX1 and the second active region RX2 may be formed on the substrate SUB. In an embodiment, the second active region RX2 may be formed on the substrate SUB doped with p-type impurities, and the first active region RX1 may be formed on an n-well in the substrate SUB. The first active region RX1 may form a p-type transistor with the gate line GL, and the second active region RX2 may form an n-type transistor with the gate line GL.

In an embodiment, at least a nanosheet, which functions as an additional active region, may be formed over each of the first active region RX1 and the second active region RX2. For example, a nanosheet stack NS may be formed over the first active region RX1 and the second active region RX2. The nanosheet stack NS may extend in the X-axis direction. A device insulating layer 11 may be formed between the first active region RX1 and the nanosheet stack NS and between the second active region RX2 and the nanosheet stack NS.

The nanosheet stack NS may function as a channel of the transistor. For example, the nanosheet stack NS over the first active region RX1 may be doped with n-type impurities and a p-type transistor may be formed on the first active region RX1. In contrast, the nanosheet stack NS over the second active region RX2 may be doped with p-type impurities and an n-type transistor may be formed on the second active region RX2. In an embodiment, the nanosheet stack NS may include silicon (Si), germanium (Ge), and silicon germanium (SiGe). In an embodiment, the nanosheet stack NS may include indium gallium arsenide (InGaAs), indium arsenide (InAs), gallium antimonide (GaSb), indium antimonide (InSb), and a combination thereof.

For example, the nanosheet stack NS may include a plurality of nanosheets NS1 to NS3 overlapping with one another in a vertical direction (Z-axis direction). In this embodiment, the nanosheet stack NS is illustrated to include three nanosheets but is not limited thereto. For example, the nanosheet stack NS may include at least two nanosheets, and the number of nanosheets is not particularly limited.

The gate line GL may cover the nanosheet stack NS and enclose each of nanosheets NS1 to NS3. The plurality of nanosheets NS1 to NS3 may have a GAA structure in which each of nanosheets NS1 to NS3 is enclosed by the gate line GL. A gate insulating layer may be provided between the nanosheet stack NS and the gate line GL.

The source and the drain S/D may be formed at both sides of the gate line GL. The source and the drain S/D may be spaced apart from each other in the X-axis direction.

An isolation trench may be formed between the first active region RX1 and the second active region RX2, and an insulating material, for example, an oxide, may be filled into the isolation trench, to thereby form a device isolation layer. The first active region RX1 and the second active region RX2 may be isolated from each other by the device isolation layer.

Referring to FIG. 3A, the backside wiring pattern ICN of the first backside metal layer BM1 may be formed as the internal connection node of the standard cell CA1, for example, the ‘a’ node. The source and the drain S/D of the standard cell CA1 may be electrically connected to the backside wiring pattern ICN through the active contact BCA, which is the backside contact, and an active via BVA. The active contact BCA may vertically penetrate the substrate SUB in the Z-axis direction and have an upper surface in contact with the source/drain S/D and a lower surface in contact with the active via BVA. The active via BVA may have an upper surface in contact with the active contact BCA and a lower surface in contact with the backside wiring pattern ICN.

In an embodiment, the active contact BCA may be formed in a trench etched in a direction (reverse direction in the Z-axis direction) toward the lower surface of the substrate SUB from the upper surface of the substrate SUB, and the active via BVA may be formed in a trench etched in a direction toward the upper surface from the lower surface of the substrate SUB (Z-axis direction). A width of the active contact BCA may gradually decrease in the reverse direction of the Z-axis direction, and a width of the active via BVA may gradually decrease in the Z-axis direction toward the upper surface from the lower surface of the substrate SUB.

Referring to FIG. 3B, the source/drain S/D of the standard cell CA1 may be electrically connected to the backside wiring pattern ICN through the active via BVA that is formed on the lower surface of the substrate SUB. In an embodiment, the active via BVA may vertically penetrate the substrate SUB in the Z-axis direction and may have an upper surface in contact with the source and the drain S/D and a lower surface in contact with the backside wiring pattern ICN.

Referring to FIG. 3C, an interlayer insulating layer 12 may be formed on the first active region RX1 and the second active region RX2. A power contact PCA and a power via PVA, which are the frontside contact, may be formed through the interlayer insulating layer 12, and thus, the patterns of the source and the drain S/D may be connected to the first metal layer M1. The power via PVA may include a via in the first via layer V0.

In an embodiment, the pattern of the first metal layer M1, which is the frontside metal layer, may be formed into the first power line PL1 for supplying the first supply voltage VDD to the standard cell CA1 and the second power line PL2 for supplying the second supply voltage VSS to the standard cell CA1. Therefore, the source and the drain S/D of the standard cell CA1 may be electrically connected to the first power line PL1 and the second power line PL2 through the power contact PCA and the power via PVA and may receive the first supply voltage VDD and the second supply voltage VSS.

Referring to FIG. 3D, the pattern of the first backside metal layer BM1, which is the backside metal layer, may be formed into the first power line PL1 for supplying the first supply voltage VDD to the standard cell CA1 and the second power line PL2 for supplying the second supply voltage VSS to the standard cell CA1. Thus, the source and the drain S/D of the standard cell CA1 may be electrically connected to the first power line PL1 or the second power line PL2 through a power via PBVA penetrating the substrate SUB and may receive the first supply voltage VDD and the second supply voltage VSS. However, unlike the configurations shown in FIG. 3D, the source and the drain S/D of the standard cell CA1 may also be electrically connected to the first power line PL1 and the second power line PL2 through the power via PBVA contacting the first power line PL1 or the second power line PL2 and a power contact, which is the backside contact, contacting the source and the drain S/D.

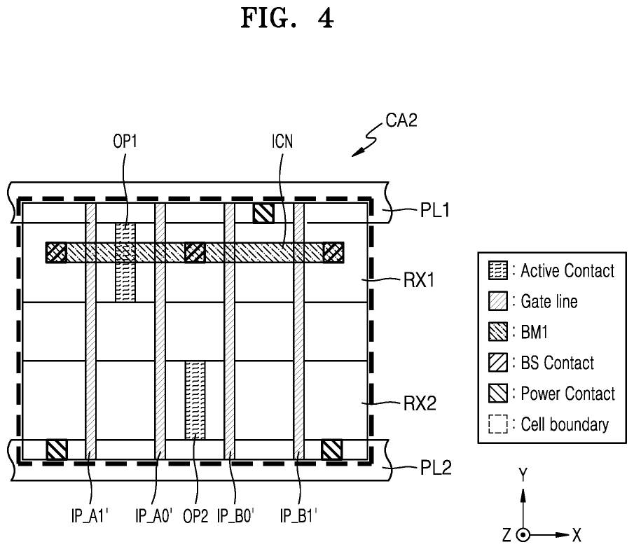

FIGS. 4 to 6, 7A, and 8 are views illustrating other examples of the standard cells CA2 to CA6 in the integrated circuit 10 according to example embodiments, and more particularly, are layouts for explaining the AND-OR-INVERTER circuit AOI22. FIG. 7B is a cross-sectional view cut along line X5-X6 of FIG. 7A according to example embodiments. In FIGS. 4 to 6, 7A, and 8, the same reference numerals denote the same elements in FIG. 2, and any further detailed descriptions on the same elements are omitted, and furthermore, in FIG. 7B, the same reference numerals denote the same elements in FIG. 3A, and any further detailed descriptions on the same elements are omitted.

Referring to FIG. 4, a standard cell CA2 according to an embodiment may include a first input pin IP_A0′ to which a first input signal A0 is input, a second input pin IP_A1′ to which a second input signal A1 is input, a third input pin IP_B0′ to which a third input signal B0 is input, a fourth input pin IP_B1′ to which a fourth input signal B1 is input, and a first output pin OP1 and a second output pin OP2 from which an output signal Y is output.

In an embodiment, the first to fourth input pins IP_A0′, IP_A1′, IP_B0′, and IP_B1′ may be formed as gate lines, and the first output pin OP1 and the second output pin OP2 may be formed as active contacts that are the frontside contacts on the first active region RX1 and the second active region RX2.

The first output pin OP1 and the second output pin OP2 may be electrically separated from each other in the standard cell CA2. When the standard cell CA2 is placed according to the design rules D14 in FIG. 12, a routing pattern for electrically connecting the first output pin OP1 to the second output pin OP2 may be formed in the operation of routing the pins S50 in FIG. 12.

Since the first output pin OP1 and the second output pin OP2 of the standard cell CA2 are not formed in the metal layer but formed as the active contact, the pattern of the first metal layer M1 and the via of the first via layer V0, which are the structure for transmitting the output signal Y, may be freely formed at such a position that the active pattern, which is the first output pin OP1 and the second output pin OP2, overlaps the pattern of the first metal layer M1 and the via of the first via layer V0 in the Z-axis direction.

The standard cell CA2 may have such a configuration that all inner patterns of the cell are not formed on the frontside metal layer. Accordingly, there may be more space for arranging the routing wirings by which the standard cell CA2 and another standard cell are electrically connected on the frontside metal layer, to thereby increase the degree of freedom of the routing wiring.

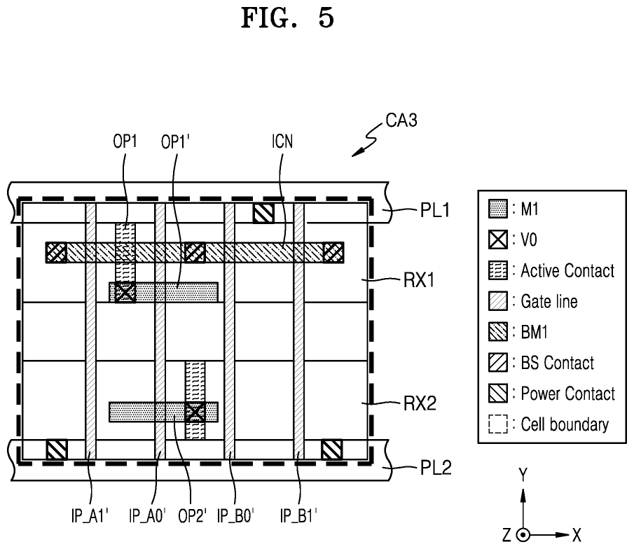

Referring to FIG. 5, a standard cell CA3 according to an embodiment may include a first input pin IP_A0′ to which a first input signal A0 is input, a second input pin IP_A1′ to which a second input signal A1 is input, a third input pin IP_B0′ to which a third input signal B0 is input, a fourth input pin IP_B1′ to which a fourth input signal B1 is input, and a first output pin OP1′ and a second output pin OP2′ from which an output signal Y is output.

In an embodiment, the first to fourth input pins IP_A0′, IP_A1′, IP_B0′, and IP_B1′ may be formed into gate lines, and the first output pin OP1′ and the second output pin OP2′ may be formed as patterns of the first metal layer M1.

The first output pin OP1′ and the second output pin OP2′ may be electrically separated from each other in the standard cell CA3. When standard cell CA3 is placed according to the design rules D14 in FIG. 12, a routing pattern for electrically connecting the first output pin OP1′ to the second output pin OP2′ may be formed in the operation of routing the pins S50 in FIG. 12.

The standard cell CA3 may have such a configuration that all inner patterns of the cell except for the first output pin OP1′ and the second output pin OP2′ are not formed on the frontside metal layer. For example, only the first output pin OP1′ and the second output pin OP2′ may be formed on the frontside metal layer. Accordingly, there may be more space for arranging the routing wirings by which the standard cell CA3 and another standard cell are electrically connected on the frontside metal layer, to thereby increase the degree of freedom of the routing wiring.

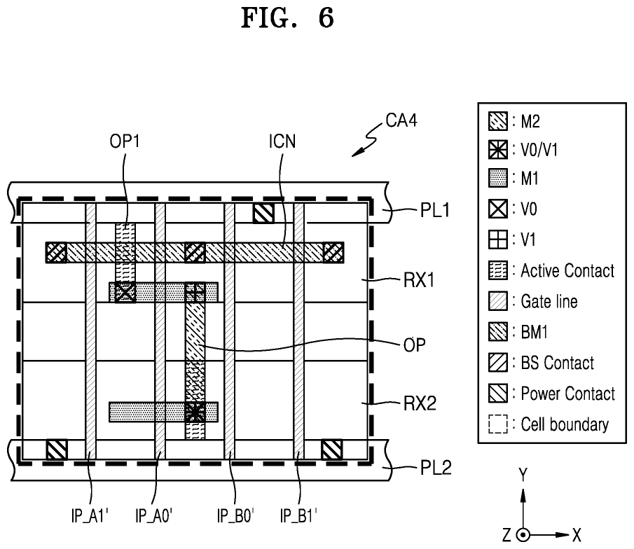

Referring to FIG. 6, a standard cell CA4 according to an embodiment may include a first input pin IP_A0′ to which a first input signal A0 is input, a second input pin IP_A1′ to which a second input signal A1 is input, a third input pin IP_B0′ to which a third input signal B0 is input, a fourth input pin IP_B1′ to which a fourth input signal B1 is input, and an output pin OP from which an output signal Y is output. In an embodiment, the first to fourth input pins IP_A0′, IP_A1′, IP_B0′, and IP_B1′ may be formed as gate lines, and the output pin OP may be formed as a pattern of the second metal layer M2.

Referring to FIGS. 7A and 7B, a standard cell CA5 according to an embodiment may include a first input pin IP_A0′ to which a first input signal A0 is input, a second input pin IP_A1′ to which a second input signal A1 is input, a third input pin IP_B0′ to which a third input signal B0 is input, a fourth input pin IP_B1′ to which a fourth input signal B1 is input, and a first output pin OP1″ and a second output pin OP2″ from which an output signal Y is output. In an embodiment, the first to fourth input pins IP_A0′, IP_A1′, IP_B0′, and IP_B1′ may be formed as gate lines, and the first output pin OP1″ and the second output pin OP2″ may be formed into active contacts.

The first output pin OP1″ and the second output pin OP2″ may be electrically connected to each other by a backside wiring pattern that is one of the inner patterns of the cell. For example, the first output pin OP1″ and the second output pin OP2″ may be connected to each other through a first backside wiring pattern ICN11 of a first backside metal layer BM1, a second backside wiring pattern ICN12 of a second backside metal layer BM2, a via BV11 of a backside via layer BV1 for connecting the first backside wiring pattern ICN11 and the second backside wiring pattern ICN12, an active contact BCA, and an active via BVA. In that case, the active contact BCA may be omitted, and the source and the drain S/D and the first backside wiring pattern ICN11 may be connected to each other by the active via BVA. Accordingly, when the standard cell CA5 is placed according to the design rules D14 in FIG. 12, a routing pattern for electrically connecting at least one of the first output pin OP1″ and the second output pin OP2″ to another standard cell may be formed in the operation of routing the pins S50 in FIG. 12.

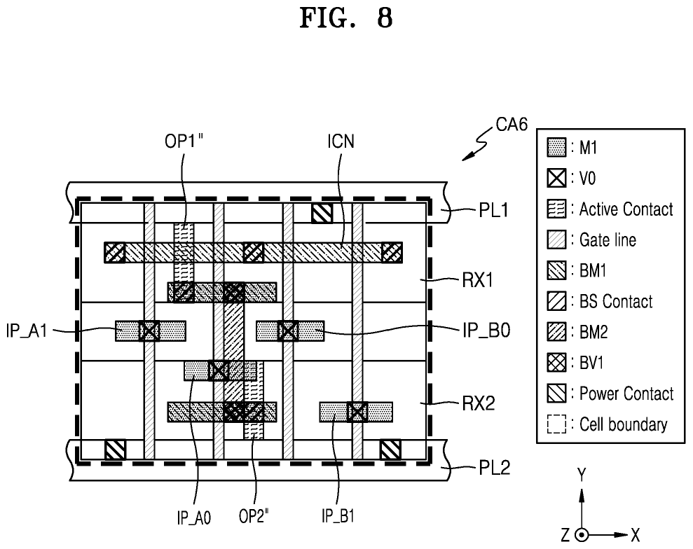

Referring to FIG. 8, a standard cell CA6 according to an embodiment may include a first input pin IP_A0 to which a first input signal A0 is input, a second input pin IP_A1 to which a second input signal A1 is input, a third input pin IP_B0 to which a third input signal B0 is input, a fourth input pin IP_B1 to which a fourth input signal B1 is input, and a first output pin OP1″ and a second output pin OP2″ from which an output signal Y is output. In an embodiment, the first to fourth input pins IP_A0, IP_A1, IP_B0, and IP_B1 may be formed as patterns of the first metal layer M1, and the first output pin OP1″ and the second output pin OP2″ may be provided as the active contacts. The first output pin OP1″ and the second output pin OP2″ may be electrically connected to each other by a backside wiring pattern that is one of the inner patterns of the standard cell CA5, and a routing pattern for electrically connecting at least one of the first output pin OP1″ and the second output pin OP2″ with another standard cell may be formed in the operation of routing the pins S50 in FIG. 12.

FIGS. 9A, 10, and 11 are views illustrating other examples of standard cells CB1 to CB3 in the integrated circuit 10 according to example embodiments, and more particularly, are layouts for explaining a flip-flop circuit. FIG. 9B is a cross-sectional view cut along line X7-X8 of FIG. 9A according to example embodiments. In FIG. 9B, the same reference numerals denote the same elements in FIG. 3A, and thus, any further detailed descriptions on the same elements are omitted.

The flip-flop circuit may receive a data input signal D, a scan input signal SI, and a scan enable signal SE and output an output signal Q according to a clock signal CK. The flip-flop circuit may store or latch the data input signal D based on the scan enable signal SE and the clock signal CK, or select the scan input signal SI to perform a scan test, to thereby output the output signal Q. The flip-flop circuit may be included in a scan chain as a scan test circuit.

Referring to FIG. 9A, a standard cell CB1 according to an embodiment may include gate lines extending in the Y-axis direction and a first active region RX1 and a second active region RX2 extending in the X-axis direction. The first active region RX1 may be referred to as a PFET region where a p-type FET is formed, and the second active region RX2 may be referred to as an NFET region where an n-type FET is formed.

The standard cell CB1 may include a first input pin IPA to which the data input signal D is input, a second input pin IPB to which the scan input signal SI is input, a third input pin IPC to which the scan enable signal SE is input, a fourth input pin IPD to which the clock signal CK is input, and an output pin OPB from which the output signal Q is output. In an embodiment, the patterns of the first metal layer M1 or the second metal layer M2 may be provided as the first to fourth input pins IPA, IPB, IPC, and IPD, and a pattern of the first metal layer M1 may be provided as the output pin OPB. For example, some patterns of the first metal layer M1 may be provided as the first, second, and fourth input pins IPA, IPB, and IPD, and the pattern of the second metal layer M2 may be provided as the third input pin IPC.

The standard cell CB1 may have such a structure that the patterns for transmitting the data input signal D, the scan input signal SI, the scan enable signal SE, and the clock signal CK, such as the first to fourth input pins IPA, IPB, IPC, and IPD, and the pattern for transmitting the output signal Q, such as the output pin OPB, may only be arranged on the frontside metal layer M1 or M2, and some backside wiring patterns, which are formed on the backside metal layer BM1 or BM2, may be provided as internal connection nodes for transmitting inner signals in the standard cell CB1. The gate lines of the standard cell CB1 and the sources/drains of the first active region RX1 and the second active region RX2 may be connected to the first backside metal layer BM1 through the backside contact. Accordingly, there may be more space for forming routing wirings by which the standard cell CB1 and another standard cell are electrically connected, to thereby increase the degree of freedom of the routing wiring.

The standard cell CB1 may receive the first supply voltage VDD through a first power line PL1 and the second supply voltage VSS through a second power line PL2. The first power line PL1 and the second power line PL2 may be formed on the first metal layer M1, as described with reference to FIG. 3C, or on the first backside metal layer BM1, as described with reference to FIG. 3D.

Referring to FIG. 9B, the standard cell CB1 may include a gate contact BCB corresponding to the backside contact in contact with the gate line GL. A backside wiring pattern ICN of the first backside metal layer BM1 may be provided as the internal connection node of the standard cell CB1. The gate line GL of the standard cell CB1 may be electrically connected to the backside wiring pattern ICN through the gate contact BCB. For example, the gate contact BCB may be one of the backside contact. The gate contact BCB may vertically penetrate the substrate SUB in the Z-axis direction, and for example, may have an upper surface in contact with the gate line GL and a lower surface in contact with the backside wiring pattern ICN.

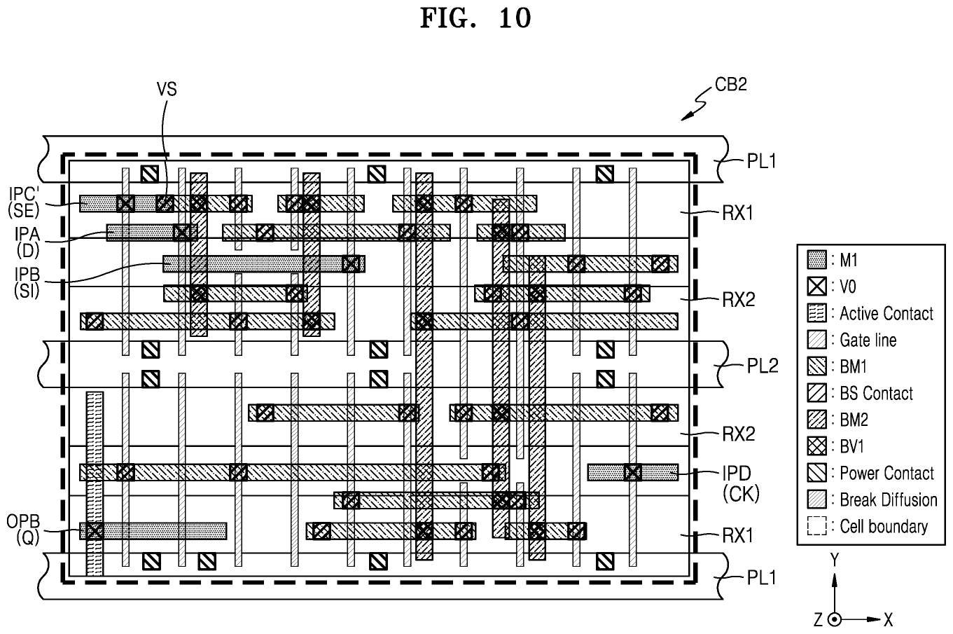

Referring to FIG. 10, a standard cell CB2 according to an embodiment may include a first input pin IPA to which the data input signal D is input, a second input pin IPB to which the scan input signal SI is input, a third input pin IPC′ to which the scan enable signal SE is input, a fourth input pin IPD to which the clock signal CK is input, and an output pin OPB from which the output signal Q is output. In an embodiment, some patterns of the first metal layer M1 may be provided as the first to fourth input pins IPA, IPB, IPC′, and IPD and the output pin OPB.

The standard cell CB2 may have such a structure that only the first to fourth input pins IPA, IPB, IPC′, and IPD and the output pin OPB may be arranged on the frontside metal layer M1, and some backside wiring patterns, which are formed on the backside metal layer BM1 or BM2, may be provided as inner patterns of the standard cell CB2. In an embodiment, the third input pin IPC′, which is formed on the first metal layer M1, may be electrically connected to the gate line to which the scan enable signal SE is to be applied through the backside wiring pattern on the first backside metal layer BM1, the backside contact, and a penetrating via structure VS interconnecting the first metal layer M1 and the first backside metal layer BM1 and penetrating the substrate SUB.

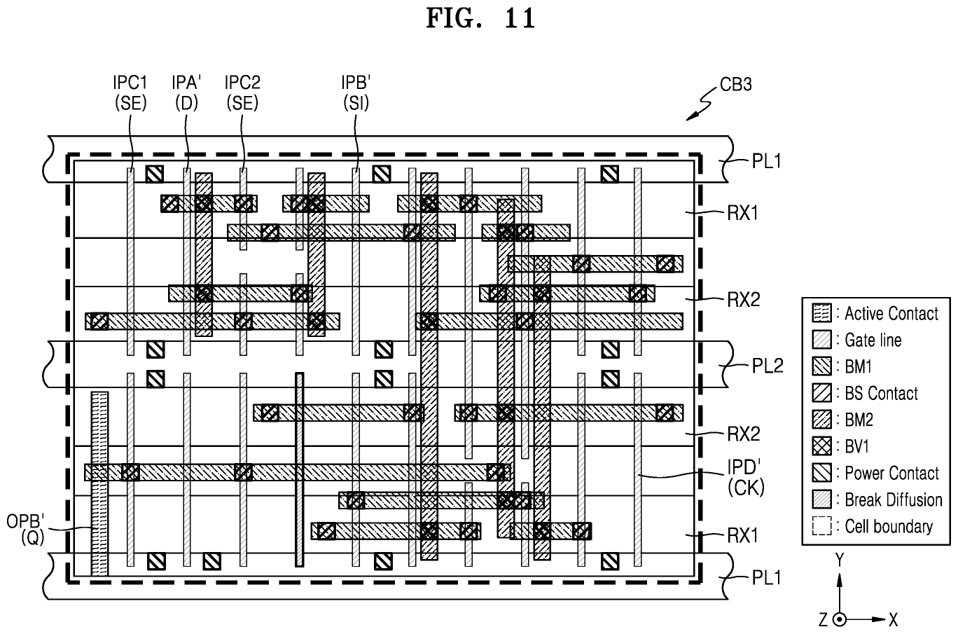

Referring to FIG. 11, a standard cell CB3 according to an embodiment may include a first input pin IPA′ to which the data input signal D is input, a second input pin IPB′ to which the scan input signal SI is input, a plurality of third input pins IPC1 and IPC2 to which the scan enable signal SE is input, a fourth input pin IPD′ to which the clock signal CK is input, and an output pin OPB′ from which the output signal Q is output. In an embodiment, the first, second, and fourth input pins IPA′, IPB′, and IPD′ and the third input pins IPC1 and IPC2 may be provided as gate lines, and the output pin OPB′ may be provided as an active contact.

In an embodiment, the third input pins IPC1 and IPC2 may not be connected to each other in the standard cell CB3. Accordingly, when the standard cell CB3 is placed according to the design rules D14 in FIG. 12, a routing pattern for electrically connecting the third input pins IPC1 and IPC2 with each other may be formed in the operation of routing the pins S50 in FIG. 12.

In another embodiment, unlike the configuration shown in FIG. 11, the third input pins IPC1 and IPC2 may be connected to each other through the inner patterns of the standard cell CB3. For example, the third input pins IPC1 and IPC2 may be electrically connected to each other by the pattern of the backside metal layer BM1 or BM2, and the routing wiring may be formed in the operation of routing pins S50 in FIG. 12 in such a way that at least one of the third input pins IPC1 and IPC2 is connected to another standard cell.

FIG. 12 is a flowchart showing a method of manufacturing an integrated circuit IC, according to an embodiment. Specifically, the flowchart in FIG. 12 shows as an example for a method of manufacturing an IC including the standard cells. As shown in FIG. 12, a method of manufacturing an IC may include a plurality of operations S10, S30, S50, S70, and S90.

A cell library or a standard cell library D12 may include information on the standard cells, for example, information on functions, characteristics, layouts, etc. of the standard cells. In some embodiments, the cell library D12 may define a tap cell and a dummy cell as well as a functional cell for generating the output signal from the input signal.

The design rule D14 may include requirements for the layout of the IC. For example, the design rule D14 may include various requirements, such as a space between patterns at the same layer, a minimum width of patterns, a routing direction of a metal layer, etc. In some embodiments, the design rule D14 may include a requirement for electrically connecting a plurality of input pins receiving the same input signal by a single node in operation of routing the pins S50.

In operation S10, a logic synthesis operation may be performed to generate netlist data D13 from RTL data D11. For example, a semiconductor design tool, for example, a logical synthesis tool, may perform the logical synthesis from the RTL data D11 written in very high-speed integrated circuit (VHSIC) hardware description language (VHDL) and hardware description language (HDL) such as Verilog with reference to the cell library D12 and generate the netlist data D13 including bitstream or netlist. The netlist data D13 may correspond to input data for placing and routing the standard cells, as described below.

In operation S30, the standard cells may be placed. For example, the semiconductor design tool. e.g., a P&R tool, may place the standard cells that are used in netlist data D13 with reference to the cell library D12. In an embodiment, the semiconductor design tool may place the standard cells in rows extending in the X-axis or Y-axis direction, and the placed standard cells may receive power from power rails, such as the first power line PL1 and the second power line PL2, extending along the boundaries of the rows. In operation S30, the standard cells C1, C2, CA1 to CA6, and CB1 to CB3 described with reference to FIGS. 1, 2, 3A, 3B, 4 to 6, 7A, 7B, 8, 9A, 9B, 10, and 11 may be placed.

In operation S50, pins of the standard cells may be routed. For example, the semiconductor design tools may generate interconnection that electrically connects the output pins and the input pins of the placed standard cells and layout data D15 that defines the placed standard cells and the generated interconnection. The interconnection may include the via of the via layer and the patterns of the metal layers, that is, the routing patterns. The metal layers may include front metal layers positioned over the gate line, such as the first metal layer M1, as well as a backside metal layer positioned under the gate line. The layout data D15 may have a data format such as graphic design system (GDS)-II (GDSII), and may include geometric information of the standard cells and the interconnection. The semiconductor design tool may refer to the design rule D14 when routing the pins of the standard cells. For example, according to the design rule D14, a routing pattern for electrically connecting a plurality of input pins to which the same input signal is input with one another by using a single node, or another routing pattern for electrically connecting a plurality of output pins from which the same output signal is output with one another by using a single node may be generated in operation S50.

The layout data D15 may correspond to output of placing and routing the standard cells. Operation S50 alone or a combination of operation S30 and operation S50 may be generally referred to as method of designing an integrated circuit.

In operation S70, an operation of manufacturing a mask may be performed. For example, an optical proximity correction (OPC) may be applied to the layout data D15 so as to correct distortion such as refraction caused by light characteristics in performing a photolithography process. A plurality of patterns for a mask for forming patterns on a plurality of layers may be defined based on the data to which OPC is applied, and at least a mask, or a photomask, for forming each pattern on the respective layer may be manufactured. In an embodiment, the layout of the integrated circuit IC may be restrictively modified in operation S70, and the restrictive modification of the integrated circuit IC in operation S70 may be a post-processing for optimizing the structure of the integrated circuit IC and may be referred to as design policing.

In operation S90, an operation of manufacturing the integrated circuit IC may be performed. For example, a plurality of layers may be patterned by using at least a mask, which is manufactured in operation S70, to thereby manufacture the integrated circuit IC that is classified into a front end of line (FEOL) process and a back end of line (BEOL) process. The FEOL process may include, for example, an operation of planarizing and cleaning a wafer, an operation of forming a trench, an operation of forming a well, an operation of forming a gate electrode, and an operation of forming the source/drain S/D. Thus, individual devices, such as transistors, capacitors, resistors, etc., may be formed on the substrate in the FEOL process. In addition, the BEOL process may include, for example, an operation of performing silicidation on the gate and source/drain regions, an operation of forming a dielectric layer, an operation of planarizing the dielectric layer, an operation of forming a hole, an operation of forming a metal layer, an operation of forming a via in the hole, and an operation of forming a passivation layer. Thus, the individual devices, such as transistors, capacitors, resistors, etc., may be connected to one another in the BEOL process. In some embodiments, a middle-of-line (MOL) process may be further performed between the FEOL process and the BEOL process, and various contacts may be formed on the individual devices. Thereafter, the integrated circuit IC may be packaged into a semiconductor package and the semiconductor package may be used as a component of various applications.

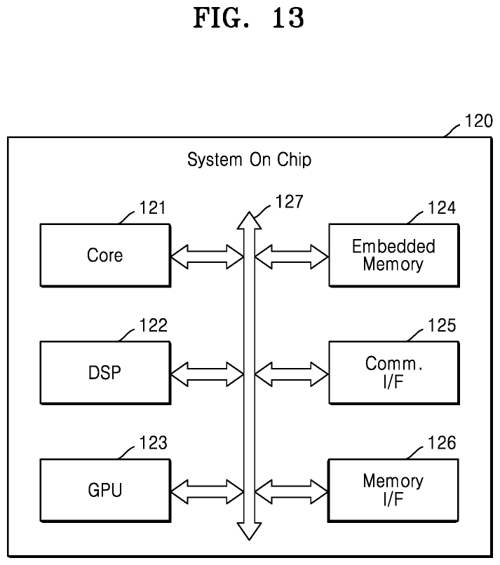

FIG. 13 is a block diagram showing a system-on-chip 120 according to an embodiment. A system on chip (SoC) 120 according to an embodiment may refer to an integrated circuit in which various components of a computing system or other electronic systems are integrated on a chip. For example, an example of the SoC 120 may include an application processor (AP) having a processor and components for other functions. As shown in FIG. 13, the SoC 120 may include a core 121, a digital signal processor (DSP) 122, a graphics processing unit (GPU) 123, an embedded memory 124, a communication interface 125, and a memory interface 126. The components of the SoC 120 may communicate with one another through a bus 127.

The core 121 may process instructions and control operations of components in the SoC 120. For example, the core 121 may run an operating system by processing a series of instructions and execute applications on the operating system. The DSP 122 may generate useful data by processing digital signals, for example, digital signals, provided from the communication interface 125. The GPU 123 may generate display data, which is output on a display device, from image data transferred from the internal memory 124 or the memory interface 126, or may encode the image data. The internal memory 124 may store data necessary for operating the core 121, the DSP 122, and the GPU 123.

The communication interface 125 may provide a communication network or an interface for one-to-one communication. The memory interface 126 may provide an interface to an external memory of the SoC 120, such as dynamic random access memory (DRAM), flash memory, etc.

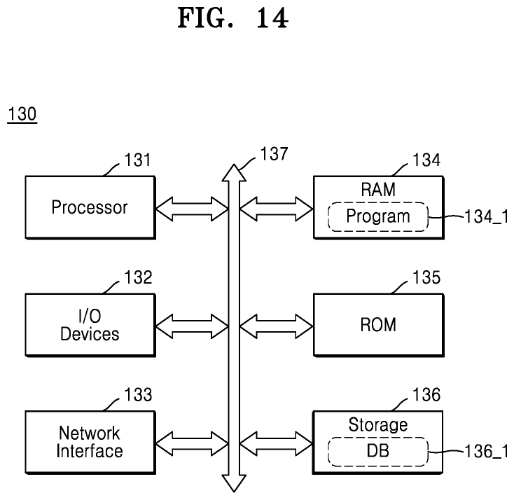

FIG. 14 is a block diagram showing a computing system 130 including a memory for storing a program according to an embodiment. At least a portion of the method of designing an integrated circuit according to some embodiments, for example, at least some of operations in the flowchart described above, may be performed in the computing system (or a computer) 130.

The computing system 130 may be a fixed computing system such as a desktop computer, a workstation, a server, or a portable computing system such as a laptop computer. As shown in FIG. 14, the computing system 130 may include a processor 131, input/output devices 132, a network interface 133, random access memory (RAM) 134, read only memory (ROM) 135, and a storage device 136. The processor 131, the input/output devices 132, the network interface 133, the RAM 134, the ROM 135, and the storage device 136 may be connected to a bus 137 and communicate with each other through the bus 137.

The processor 131 may be referred to as processing unit and may include at least a core capable of performing an arbitrary command set (e.g., intel architecture (IA)-32, 64 bit extension IA-32, x86-64, Power PC, Sparc, MIPS, ARM, IA-86, etc.), such as a microprocessor, an AP, a digital signal processor (DSP), and a GPU. For example, the processor 131 may have access to the memory, that is, the RAM 134 or the ROM 135, through the bus 137 and execute the commands stored in the RAM 134 or the ROM 135.

The RAM 134 may store a program 134_1 or at least a portion of the program 134_1 for a method of designing the integrated circuit according to an embodiment, and the program 134_1 may make the processor 131 perform the method of designing an integrated circuit, for example, at least some of operations for a method of designing an integrated circuit shown FIG. 12. That is, the program 134_1 may include a plurality of instructions executable by the processor 131, and the plurality of instructions in the program 134_1 may make the processor 131 perform, for example, at least some of operations in the flowchart described above.

The storage device 136 may not lose the stored data although the power supplied to the computing system 130 is turned off. For example, the storage device 136 may include a nonvolatile memory device and a storage medium such as a magnetic tape, an optical disk, and a magnetic disk. In addition, the storage device 136 may be detachable from the computing system 130. The storage device 136 may store the program 134_1 according to an embodiment, and the program 134_1 or at least a portion of the program 134_1 may be loaded into the RAM 134 from the storage device 136 before the program 134_1 is executed by the processor 131. Otherwise, the storage device 136 may store a coding file written in a program language, and the program 134_1, which is generated by compiling the coding file, or at least a portion thereof may be loaded into the RAM 134. In addition, as shown in FIG. 14, the storage device 136 may store a database 136_1 having information necessary for designing the integrated circuit, for example, information on the designed blocks and the cell library D12 and/or the design rule D14 shown in FIG. 12.

The storage device 136 may store data to be processed by the processor 131 or data processed by the processor 131. That is, the processor 131 may generate data by processing stored data in the storage device 136 according to the program 134_1 and may store the generated data in the storage device 136. For example, the storage device 136 may store the RTL data D11, the netlist data D13, and/or the layout data D15 shown in FIG. 12.

The input/output devices 132 may include an input device, such as a keyboard and a pointing device, and an output device such as a display device and a printer. For example, the user may control the processor 131 and trigger the execution of the program 134_1, input the RTL data D11 and/or the netlist data D13 shown in FIG. 12, and check the layout data D15 shown in FIG. 12 by using the input/output devices 132.

The network interface 133 may provide access to an external network outside the computing system 130. For example, the external network may include a plurality of computing systems and communication links, and the communication link may include wired links, optical links, wireless links, and any other type of link.

Embodiments have been disclosed in the drawings and specification as described above. Embodiments have been described using specific terms in the present specification, but this is used only for the purpose of describing the technical idea of the present disclosure and is not used to limit the scope of the present disclosure described in the meaning or patent claims. Therefore, those of ordinary skill in the art will understand that various modifications and equal other embodiments are possible from this.

While the inventive concept has been particularly shown and described with reference to embodiments thereof, it will be understood that various changes in form and details may be made therein without departing from the spirit and scope of the following claims.

What is claimed is:

1. An integrated circuit comprising:
a substrate; and
a plurality of standard cells on the substrate,
wherein a standard cell of the plurality of standard cells includes:
a backside wiring pattern arranged on a lower portion of the substrate and including at least an internal connection node of the standard cell; and
a plurality of gate lines arranged on an upper portion of the substrate and extending in a first horizontal direction,
wherein at least one of the plurality of gate lines functions as an input pin of the standard cell.

2. The integrated circuit of claim 1, wherein the standard cell further includes:
a plurality of active regions arranged on the upper portion of the substrate and extending in a second horizontal direction; and
a plurality of active contacts in contact with the plurality of active regions, respectively, and
wherein at least one of the plurality of active contacts functions as an output pin of the standard cell.

3. The integrated circuit of claim 1, further comprising:
a first power line arranged at the lower portion of the substrate and configured to supply a first supply voltage to the plurality of standard cells; and
a second power line arranged at the lower portion of the substrate and configured to supply a second supply voltage lower than the first supply voltage to the plurality of standard cells.

4. The integrated circuit of claim 1, wherein the standard cell further includes:
a first power line arranged at the upper portion of the substrate and configured to supply a first supply voltage to the standard cell; and
a second power line arranged at the upper portion of the substrate and configured to supply a second supply voltage lower than the first supply voltage to the standard cell.

5. The integrated circuit of claim 1, wherein the plurality of gate lines include a first gate line and a second gate line that are provided as input pins configured to receive the same input signal, and
wherein the first gate line and the second gate line are electrically separated from each other in the standard cell.

6. The integrated circuit of claim 1, wherein the plurality of gate lines include a first gate line and a second gate line that are provided as input pins configured to receive the same input signal, and
wherein the first gate line and the second gate line are electrically connected to each other by the backside wiring pattern.

7. The integrated circuit of claim 1, further comprising:
a routing pattern electrically connecting the standard cell to another standard cell of the plurality of standard cells,
wherein the routing pattern is formed on a backside metal layer that is provided at the lower portion of the substrate.

8. An integrated circuit comprising:
a substrate; and
a plurality of standard cells on the substrate,
wherein a standard cell of the plurality of standard cells includes:
a backside wiring pattern arranged on a lower portion of the substrate including at least an internal connection node of the standard cell;
a frontside wiring pattern formed on an upper portion of the substrate including:
an input pin configured to receive an input signal, and
an output pin configured to output an output signal; and
a backside contact connecting the backside wiring pattern to an active region of the substrate and penetrating the substrate.

9. The integrated circuit of claim 8, wherein only the input pin and the output pin are formed into the frontside wiring pattern on the upper portion of the substrate.

10. The integrated circuit of claim 8, wherein the standard cell further includes:
a first power contact connecting to a first power rail that is arranged at the lower portion of the substrate and configured to supply a first supply voltage; and
a second power contact connected to a second power rail that is arranged at the lower portion of the substrate and configured to supply a second supply voltage lower than the first supply voltage.

11. The integrated circuit of claim 8, wherein the backside wiring pattern includes:
a first backside wiring pattern of a first backside metal layer that is arranged at the lower portion of the substrate; and
a second backside wiring pattern of a second backside metal layer that is arranged at a lower portion of the first backside metal layer, and
wherein the first backside metal layer includes a plurality of patterns extending in a first horizontal direction, and the second backside metal layer includes a plurality of patterns extending in a second horizontal direction perpendicular to the first horizontal direction.

12. The integrated circuit of claim 8, wherein the frontside wiring pattern includes a first frontside wiring pattern and a second frontside wiring pattern that are provided as output pins configured to output the same output signal is output, and
wherein the first frontside wiring pattern and the second frontside wiring pattern are electrically separated from each other in the standard cell.

13. The integrated circuit of claim 8, wherein the frontside wiring pattern includes a first frontside wiring pattern and a second frontside wiring pattern that are provided as output pins configured to output the same output signal, and
wherein the first frontside wiring pattern and the second frontside wiring pattern are electrically connected to each other by the backside wiring pattern.

14. The integrated circuit of claim 8, wherein the frontside wiring pattern includes a plurality of patterns that are provided as output pins formed on a second metal layer positioned at an upper portion of a first metal layer and configured to output the same output signal.

15. The integrated circuit of claim 8, further comprising:
a plurality of gate lines horizontally extending on the upper portion of the substrate,
wherein at least one of the plurality of gate lines functions as an input pin.

16. The integrated circuit of claim 15, wherein the plurality of gate lines include a first gate line and a second gate line that are provided as input pins configured to receive the same input signal, and
wherein the first gate line and the second gate line are electrically separated from each other in the standard cell.

17. The integrated circuit of claim 15, wherein:
the plurality of gate lines include a first gate line and a second gate line that are provided as input pins configured to receive the same input signal, and
the first gate line and the second gate line are electrically connected to each other by the backside wiring pattern.

18. An integrated circuit comprising:
a substrate; and
a plurality of standard cells on the substrate,
wherein a standard cell of the plurality of standard cells includes:
a backside wiring pattern arranged on a lower portion of the substrate including at least an internal connection node of the standard cell;
a plurality of gate lines arranged on an upper portion of the substrate and extending in a first horizontal direction;
a plurality of active regions arranged on the upper portion of the substrate and extending in a second horizontal direction perpendicular to the first horizontal direction; and
a plurality of active contacts in contact with the plurality of active regions, respectively,
wherein at least one of the plurality of active contacts functions as an output pin of the standard cell.

19. The integrated circuit of claim 18, wherein the plurality of active contacts include a first active contact and a second active contact that are provided as output pins configured to output the same output signal, and
wherein the first active contact and the second active contact are electrically separated from each other in the standard cell.

20. The integrated circuit of claim 18, wherein the plurality of active contacts include a first active contact and a second active contact that are provided as output pins configured to output the same output signal, and
wherein the first active contact and the second active contact are electrically connected to each other by the backside wiring pattern.
